(19) United States
(12) Patent Application Publication
(10) Pub. No.: US 2002/0167087 A1
(43) Pub. Date: Nov. 14, 2002

(54) Insulating member and a method for manufacturing the same

(76) Inventors: Bryan Charles Dingel, Boise, ID (US); Min-Chen Shiue, Luo Tung (CN)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 09/853,049

(22) Filed: May 9, 2001

(51) Int. Cl. H01L 23/48

(52) U.S. Cl. 257/758

(57) ABSTRACT

An insulating member comprising a first nylon layer sandwiched between a first and second layer of neoprene. The member further comprises a second nylon layer attached to the second neoprene layer, such that the second neoprene layer is sandwiched between the first and second nylon layers. The method of binding the insulating member comprises threading a stitch from one side of the insulated member to penetrate the second nylon layer of a first insulated member and binding first neoprene layer of a second insulating member by threading the stitch through the first neoprene and nylon layer of the second member, wherein each stitch does not penetrate the second neoprene layer of each member.

### FIELD OF THE INVENTION

The present invention relates to an insulated material and, more particularly, the present invention relates to an insulated material for protective clothing and a method for manufacturing the same.

### BACKGROUND OF THE INVENTION

Gloves, wetsuits, and other similar clothing are typically made of a rubber composite or a layer of Neoprene material. Although known rubber composites and other synthetic materials are effective for the construction of waterproof clothing, these existing materials do not provide a durable material with exceptional insulating qualities. In addition, conventional methods of binding generally known waterproof materials do not effectively provide a seam having high strength qualities or retain their waterproof quality after they have been stressed. Accordingly, there is a need for an improved material having waterproof and insulating qualities. In addition, there is a need for an improved method of binding waterproof materials.

### SUMMARY OF THE INVENTION

The present invention relates generally to an insulating material having improved strength and insulation qualities. In one embodiment, the insulating material includes a first nylon layer bonded to a composition that includes a second nylon layer that is sandwiched between first and second neoprene layers. The first and second neoprene layers are disposed on each side of the first nylon layer by the use of a neoprene-based adhesive. The second nylon layer is suitably bonded to the first neoprene layer by the use of a neoprene-based adhesive. In one embodiment, the first and second neoprene layers have a thickness of at least 1.5 mm.

In another aspect of the present invention, a method for binding two sections of insulating material is provided. In one embodiment, a first section of insulating material is bonded to a second section of insulating material by the use of a waterproof adhesive and at least one stitch configured at predetermined depths in the insulating material.

In one embodiment, the method involves binding a first section of material to a second section of material by providing a first section having a first nylon layer sandwiched between first and second neoprene layers, and a second nylon layer bonded to the first neoprene layer opposite the first nylon layer. In addition, the method involves providing a second section having a first nylon layer sandwiched between first and second neoprene layers, and a second nylon layer bonded to the first neoprene layer opposite the first nylon layer. The edges of the first and second sections are positioned together.

The first and second sections are bound together by sewing a first stitch between the first and second sections such that the first stitch is positioned to extend through the second neoprene layer and the first nylon layer of the first and second sections. The first stitch is positioned such that it enters into the first neoprene layer from the first nylon layer without passing through the first neoprene layer of the first and second sections. The method also includes sewing a second stitch through the edges of each section. Suitably, the second stitch extends through the second nylon layer of the first and second sections. In certain embodiments, the second stitch extends into the first neoprene layer from the second nylon layer without passing through the first neoprene layer of the first and second sections.

### BRIEF DESCRIPTION OF THE DRAWINGS

The foregoing aspects and many of the attendant advantages of this invention will become better understood by reference to the following detailed description, when taken in conjunction with the accompanying drawings, wherein:

FIG. 1A is a perspective and partially exploded view of one embodiment of an insulated member in accordance with one aspect of the present invention;

FIG. 1B is a section of the insulated member shown in FIG. 1A;

FIG. 2 is a section of two insulating members coupled by a stitch in accordance with another aspect of the present invention; and

FIG. 3 is a section of one insulating member by a stitch to a multi-layered insulating member and formed in accordance with one embodiment of the present invention.

### DETAILED DESCRIPTION OF THE PREFERRED EMBODIMENT

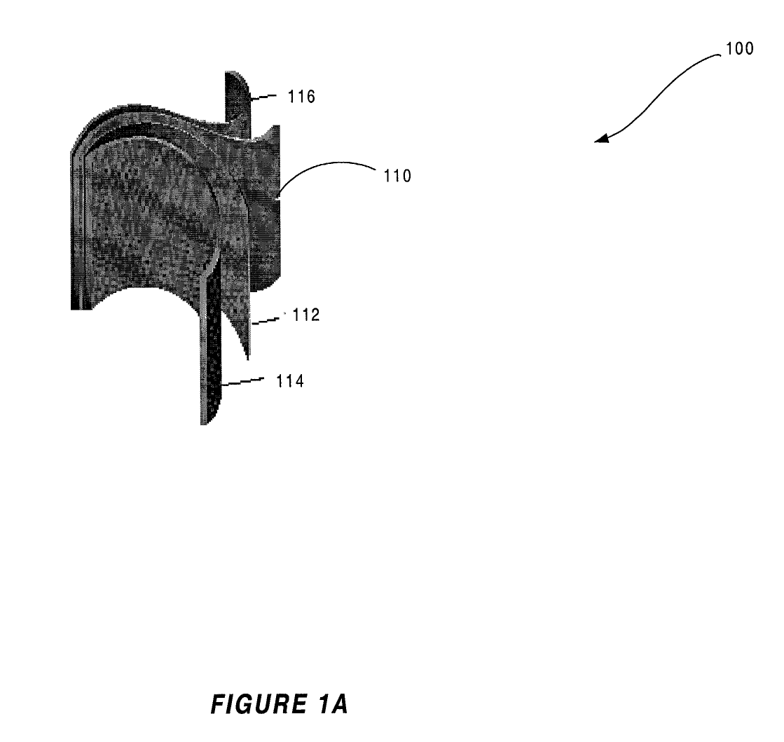

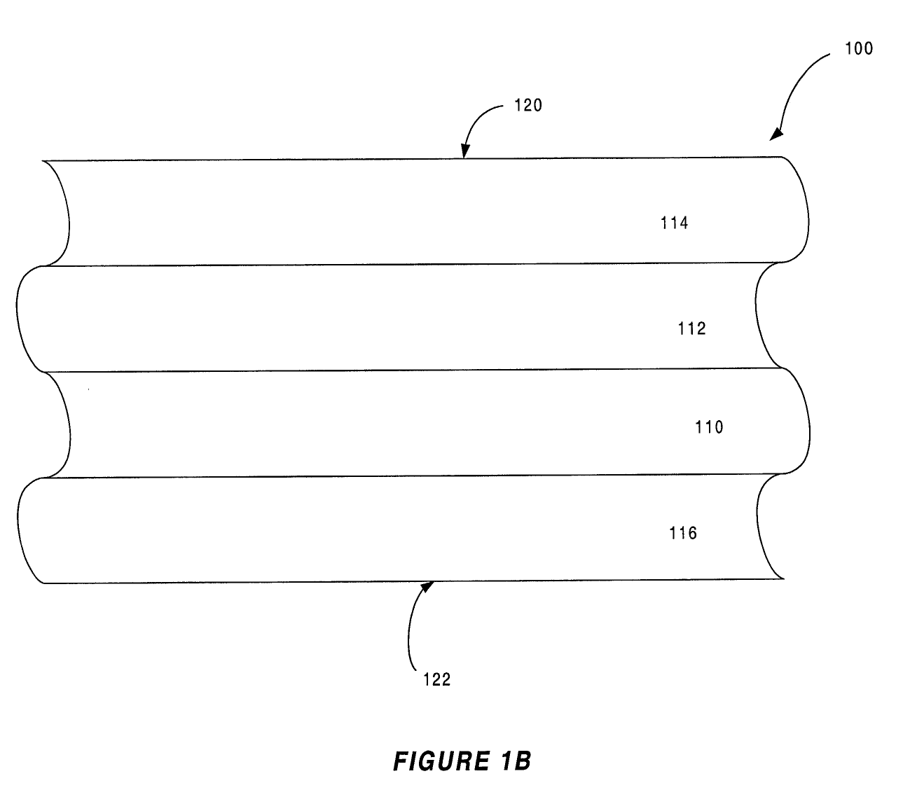

FIGS. 1A and 1B illustrate an insulating member 100 formed in accordance with one embodiment of the present invention. The insulating member 100 includes a first nylon layer 112 sandwiched between first and second neoprene layers 110 and 114. The first and second neoprene layers 110 and 114 are affixed to the first nylon layer 112 by the use of a neoprene-based adhesive. The insulating member 100 also includes a second nylon layer 116 affixed to one of the neoprene layers 110 or 114. In the embodiment of FIGS. 1A and 1B, the second nylon layer 116 is affixed to the first neoprene layer 110 by the use of a neoprene-based adhesive. A top surface 120 is formed by the second neoprene layer 114 and a bottom surface 122 is formed by the second nylon layer 116. While normally used in a substantially horizontally orientation, the invention is not intended to be so limited. Therefore, terminology such as top, bottom, etc., should be construed as descriptive, and not limiting.

In one non-limiting example, the first and second neoprene layers 110 and 114 have a thickness approximate of 1.5 mm, and the insulating member 100 also has an overall thickness of at least 3 mm. Although an insulating member having neoprene layers having an approximate thickness of 1.5 mm, neoprene layers having a thickness greater or less than 1.5 mm, such as 1.5 and 7 mm, are also within the scope of the present invention. The neoprene layers may be constructed of a well-known neoprene material produced by DuPont™ Inc. The first and second nylon layers 112 and 116 may be constructed of any nylon material or any other like flexible fabric such as polyester, Lycra, or Spandex.

The insulating member 100 has numerous suitable uses, such as a fabric for protective clothing, where temperature insulation is desired. In one example, the insulating member 100 may be formed as a glove that provides temperature insulation and a textured surface to provide a gripping surface. When used in any clothing application, the insulating member 100 may be suitably positioned such that the bottom layer 122 is positioned toward the interior of the clothing.

In another aspect of the present invention, a method for binding two sections of the above-described insulating material is provided. In one embodiment, a first section of an insulating material is attached to a second section of insulating material by the use of a waterproof adhesive and two stitches configured at predetermined depths in the insulating material.

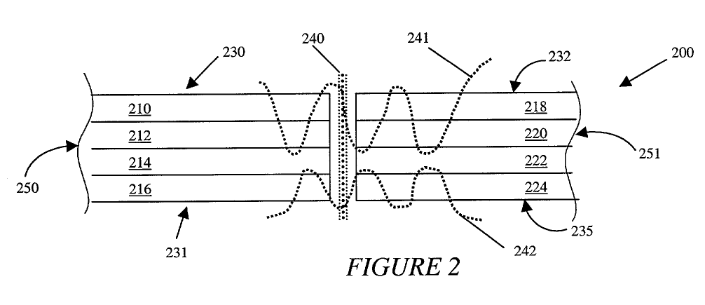

Referring now to FIG. 2, one illustration of an embodiment of two bound sections of an insulating material 200 is shown and described. A first section 250 and a second section 251 of insulating material 200 are bound together by an adhesive 240 and first and second stitches 241 and 242. In this embodiment, the first section 250 of the insulating material 200 includes a first nylon layer 212 sandwiched between first and second neoprene layers 214 and 210. The first section 250 also includes a second nylon layer 216 affixed to the first neoprene layer 214 on a side opposite the first neoprene layer 214 to which the first nylon layer 212 is affixed.

The second section 251 includes a first nylon layer 220 sandwiched between first and second neoprene layers 222 and 218. The second section 251 also includes a second nylon layer 224 affixed to the first neoprene layer 222 on a side opposite the first neoprene layer 222 to which the first nylon layer 220 is affixed. The edges of the first and second sections 250 and 251 are joined by an adhesive 240. The adhesive 240 is configured to create a waterproof seal between the two sections 250 and 251. Any waterproof adhesive may be applied between the two sections; however, a neoprene-based adhesive is preferred.

In addition to the application of the adhesive 240, the two sections 250 and 251 are also affixed by a first stitch 241 extending between the first and second sections 250 and 251. The first stitch 241 is configured to traverse through the second neoprene layers 210 and 218 and the first nylon layers 212 and 220 of the first and second sections 250 and 251, respectively. The first stitch 241 is positioned such that it enters into the first neoprene layers 214 and 222 of each section 250 and 251 from the first nylon layers 212 and 220. It is preferred that the first stitch 241 does not pass through the first neoprene layers 214 and 222 of the first and second sections 250 and 251.

The two sections are also bound by a second stitch 242 extending through the edges of each section 250 and 251, wherein the second stitch 242 is positioned to traverse through the second nylon layers 216 and 224 of the first and second sections 250 and 251. The second stitch 242 is positioned such that it enters into the first neoprene layer 214 and 222 from the second nylon layers 216 and 224. The second stitch 242 is configured such that it does not pass through the first neoprene layers 216 and 222 of the first and second sections 250 and 251. As can be appreciated to one of ordinary skill in the art, the above-described stitching technique may be implemented by a machine capable of producing a stitch at a predetermined depth or any device capable of producing a “blind” stitch.

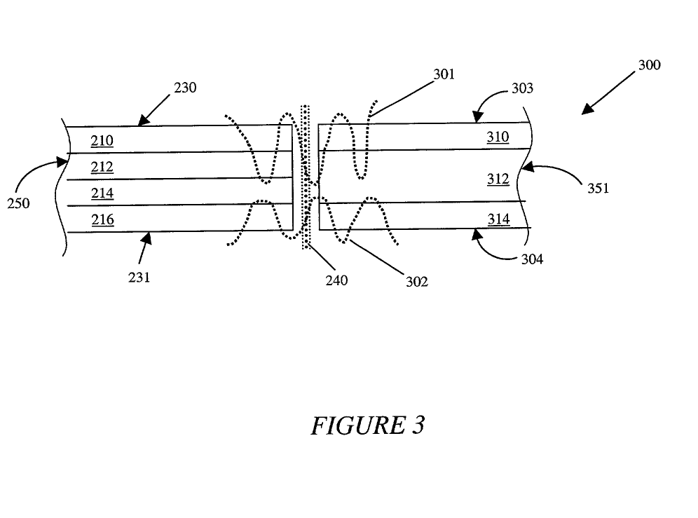

Referring now to FIG. 3, another embodiment of two bound sections of an insulating material 300 is shown and described. A first section 250 and a second section 351 of an insulating material 300 are bound together by an adhesive 240 and a first and second stitches 301 and 302. In this embodiment, the first section 250 includes a first nylon layer 212 sandwiched between first and second neoprene layers 214 and 210. The first section 250 also includes a second nylon layer 216 affixed to the first neoprene layer 214. The construction of the first section 250 is similar to the construction of the first section 250 described above with reference to FIG. 2. The second section 351 includes a neoprene layer 312 sandwiched between first and second nylon layers 310 and 314. Similar to the construction of the above-described sections, each layer of the second section 351 are laminated to one another by the use of an adhesive, such as a neoprene-based adhesive.

The first and second sections 250 and 351 are bound together by first applying an adhesive 240 between the two sections 250 and 351. Similar to the embodiment of FIG. 2, the adhesive 240 is configured between the two sections 250 and 351 such that the adhesive 240 creates a waterproof seal between the two sections 250 and 351. The two sections 250 and 351 are further secured by a first stitch 301 that is configured to pass between the first and second sections 250 and 351. The first stitch 301 is positioned to traverse through the second neoprene layer 210 and the first nylon layer 212 of the first section 250. It is preferred that the depth of the stitch is configured such that the stitch only passes through the first nylon layer 212 and the second neoprene layer 210. It is also preferred that the first stitch is set at a depth such that it does not pass through the first neoprene layer 214. As the first stitch 301 passes between the two sections 250 and 351, the first stitch 301 is configured to pass and traverse through the first nylon layer 310 of the second section 351 and configured such that the first stitch 301 does not pass through the neoprene layer 312.

In the embodiment of FIG. 3, the union of the first and second sections 250 and 351 are further secured by the use of a second stitch 302. In this embodiment, the second stitch 302 is configured to penetrate and traverse through the second nylon layer 216 of the first section 250, pass between the first and second sections 250 and 351, and then continue traversing through the second nylon layer 314. The second stitch 302 is set at a predetermined depth in each section such that the second stitch 302 does not pass through the first nylon layer 214 of the first section 250 or the neoprene layer 312 of the second layer 351. As can be appreciated to one of ordinary skill in the art, the predetermined stitch depth can be controlled by any machine capable of producing a “blind” stitch.

While preferred embodiments of the invention have been illustrated and described, it will be appreciated that various changes can be made therein without departing from the spirit and scope of the invention.

The embodiments of the invention in which an exclusive property or privilege is claimed are defined as follows:

1. An insulating member, comprising:
a first nylon layer sandwiched between a first and second neoprene layer, wherein said first and second neoprene layers are each laminated on opposite sides of said first nylon layer;
a second nylon layer laminated to at least one neoprene layer.

2. The insulating member of claim 1, wherein said second nylon layer is laminated to said first neoprene layer.

3. The insulating member of claim 1, wherein said second nylon layer is laminated to said second neoprene layer.

4. The insulating member of claim 1, wherein said first and second neoprene layer each have a thickness of at least 1.5 millimeters.

5. The insulating member of claim 1, wherein said member has a thickness of at least 3 millimeters.

6. The insulating member of claim 1, wherein said first and second neoprene layers are laminated on each side of said first nylon layer by the use of a neoprene-based adhesive.

7. The insulating member of claim 1, wherein said second nylon layer is laminated to at least one neoprene layer by the use of a neoprene-based adhesive.

8. An insulating member, comprising:
a first section comprising a first nylon layer sandwiched between a first and second neoprene layer, and a second nylon layer laminated to said first neoprene layer opposite said first nylon layer;
a second section comprising a first nylon layer sandwiched between a first and second neoprene layer, and a second nylon layer laminated to said first neoprene layer opposite said first nylon layer, wherein said edges of said first and second sections are positioned together;
a first stitch for binding said first and second sections, wherein said first stitch is positioned to pass through said edges of each section, wherein said first stitch is positioned to traverse through said second neoprene layer and said first nylon layer of said first and second sections, and wherein said first stitch is positioned such that it enters into said first neoprene layer and not through said first neoprene layer of said first and second sections; and
a second stitch for binding said first and second sections, wherein said second stitch is positioned to pass through said edges of each section, wherein said second stitch is positioned to traverse through said second nylon layer of said first and second sections, and wherein said second stitch is positioned such that it enters into said first neoprene layer and not through said first neoprene layer of said first and second sections.

9. The insulating member of claim 8, further comprising an adhesive applied between said first and second sections.

10. The insulating member of claim 9, wherein said adhesive comprises a neoprene-based adhesive.

11. The insulating member of claim 8, wherein said first and second sections are positioned in one plane.

12. The insulating member of claim 8, wherein said first stitch is in said form of a blind stitch.

13. The insulating member of claim 8, wherein said second stitch is in said form of a blind stitch.

14. An insulating member, comprising:
a first section comprising a first nylon layer laminated between a first and second neoprene layer, and a second nylon layer laminated to said first neoprene layer opposite said first nylon layer;
a second section comprising a neoprene layer laminated between a first and second nylon layer, wherein said edges of said first and second sections are positioned together;
a first stitch for binding said first and second sections, wherein said first stitch is positioned to pass through said edges of each section, wherein said first stitch is positioned to traverse through said second neoprene layer and said first nylon layer of said first section, and wherein said first stitch is positioned to traverse through said first nylon layer of said second section and not through said neoprene layer of said second section; and
a second stitch for binding said first and second sections, wherein said second stitch is positioned to pass through said edges of each section, wherein said second stitch is positioned to traverse through said second nylon layer of said first section, and wherein said second stitch is positioned to traverse through said second nylon layer of said second section and not through said neoprene layer of said second section.

15. The insulating member of claim 14, further comprising an adhesive applied between said first and second sections.

16. The insulating member of claim 15, wherein said adhesive comprises a neoprene-based adhesive.

17. The insulating member of claim 14, wherein said first and second sections are positioned in one plane.

18. The insulating member of claim 14, wherein said first stitch is in said form of a blind stitch.

19. The insulating member of claim 14, wherein said second stitch is in said form of a blind stitch.

20. A method of binding a first and second section of insulating material, wherein said method comprises:
providing a first section comprising a first nylon layer sandwiched between a first and second neoprene layer, and a second nylon layer laminated to said first neoprene layer opposite said first nylon layer;
providing a second section comprising a first nylon layer sandwiched between a first and second neoprene layer, and a second nylon layer laminated to said first neoprene layer opposite said first nylon layer, wherein said edges of said first and second sections are positioned together;
sewing a first stitch for binding said first and second sections, wherein said first stitch is positioned to pass through said edges of each section, wherein said first stitch is positioned to traverse through said second neoprene layer and said first nylon layer of said first and second sections, and wherein said first stitch is positioned such that it enters into said first neoprene layer and not through said first neoprene layer of said first and second sections; and
sewing a second stitch for binding said first and second sections, wherein said second stitch is positioned to pass through said edges of each section, wherein said second stitch is positioned to traverse through said second nylon layer of said first and second sections, and wherein said second stitch is positioned such that it enters into said first neoprene layer and not through said first neoprene layer of the first and second sections.

21. The method of claim 20, further comprising applying an adhesive between said first and second sections for creating a seal between the two sections.
